(19) United States
(12) Patent Application Publication
(10) Pub. No.: US 2026/0184973 A1
(43) Pub. Date: Jul. 2, 2026

(54) OPTICAL ADHESIVE AND LAMINATE FOR FLEXIBLE PANEL

(71) Applicant: INDUSTRIAL TECHNOLOGY RESEARCH INSTITUTE, Hsinchu (TW)

(72) Inventors: De-Qun Zhan, Taoyuan City (TW); Jiun-You Liou, Changhua County (TW); Chao-Jen Li, Hsinchu City (TW); Zhen-Yu Hung, Hsinchu County (TW); Ming-Hsueh Chiang, Kaohsiung City (TW); Chien-Hsien Cheng, Tainan City (TW); Huang-Jan Huang, Tainan City (TW)

(73) Assignee: INDUSTRIAL TECHNOLOGY RESEARCH INSTITUTE, Hsinchu (TW)

(21) Appl. No.: 19/280,354

(22) Filed: Jul. 25, 2025

(30) Foreign Application Priority Data
Dec. 31, 2024 (CN) 202411991157.5

(51) Int. Cl. C09J 133/08; C09J 4/00; H10K 77/10

(52) U.S. Cl. CPC C09J 133/08; C09J 4/00; H10K 77/111

(57) ABSTRACT

An optical adhesive and a laminate for a flexible panel are provided. The optical adhesive includes 100 parts by weight of an ingredient (A), wherein the ingredient (A) is a resin prepolymer having a straight side-chain; 0.02 to 1 part by weight of an ingredient (B), wherein the ingredient (B) is a crosslinking agent; and 0.005 to 0.01 parts by weight of an ingredient (C), wherein the ingredient (C) is a catalyst. The ingredient (A) is obtained by reacting the following composition: 10-40 parts by weight of a soft monomer, 2-15 parts by weight of a hard monomer, 1 part by weight of a hydroxyl-containing monomer, and 0.001-0.03 parts by weight of a thermal initiator. The soft monomer includes a soft acrylate monomer having a straight-chain and the hard monomer includes an unsaturated ethylene double-bond monomer.

### CROSS-REFERENCE TO RELATED APPLICATION

This non-provisional application claims priority under 35 U.S.C. § 119 (a) to patent application No. 202411991157.5 filed in China on Dec. 31, 2024, the entire contents of which are hereby incorporated by reference.

### TECHNICAL FIELD

The present disclosure relates an optical adhesive and a laminate for a flexible panel.

### BACKGROUND

Traditionally, glass plates have been widely used as a protective layer for various display panels. However, glass plates have several drawbacks, including their heavy weight, ease of breakage, and environmental issues due to high carbon emissions.

In order to solve the above limitations, along with the trend toward thinner and lighter displays and electronic devices, flexible plates made of such as acrylic and polycarbonate have been used as protective layers instead of glass plates.

However, during winding storage and transportation or under environmental thermal shocks, panels using these flexible protective layers are likely to experience delamination or warpage (failure to recover flatness) issues. The problems may be caused by the creep of molecules of the adhesive material, which is used for bonding the panel and the protective layer, or due to a mismatch in viscoelasticity and Poisson's ratio between the adhesive material and the protective layer.

For the above possible reasons, thermal stress may be generated among the layers of the panel module during bending or when subjected to high-temperature and high-humidity testing, thereby leading to delamination and deteriorating the quality of the panel module.

### SUMMARY

The present disclosure provides an optical adhesive and a laminate for a flexible panel.

In some embodiments, an optical adhesive is provided and includes 100 parts by weight of an ingredient (A), 0.02-1 part by weight of an ingredient (B) and 0.005-0.01 parts by weight of an ingredient (C). The ingredient (A) is a resin prepolymer having a straight side-chain. The ingredient (B) is a crosslinking agent. The ingredient (C) is a catalyst. The ingredient (A) is obtained by reacting a composition of: (a) 10 to 40 parts by weight of a soft monomer, (b) 2 to 15 parts by weight of a hard monomer, (c) 1 part by weight of a hydroxyl-containing monomer, and (d) 0.001 to 0.03 parts by weight of a thermal initiator. The soft monomer (a) includes a soft acrylate monomer having a straight-chain. The soft acrylate monomer has a structure represented by Formula (I), wherein n is an integer of 7 to 15. The hard monomer includes an unsaturated ethylene double-bond monomer.

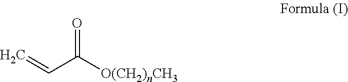

In some embodiments, a laminate for a flexible panel is further provided and includes the aforementioned optical adhesive; and a substrate, wherein the optical adhesive is arranged on a surface of the substrate.

### DETAILED DESCRIPTION

To enable the objectives, technical features and advantages of the present disclosure to be further understood by those skilled in the art to implement the present disclosure, the technical features and embodiments of the present disclosure are described in the following description and further described by listing preferred embodiments. However, the following embodiments are not used to limit the present disclosure.

### [Term Definition and Illustration]

### <Tg>

In the present description, Tg represents a glass transition temperature.

### <Optical Adhesive>

The present disclosure provides an optical adhesive, including an ingredient (A): a resin prepolymer having a straight side-chain, an ingredient (B): a crosslinking agent, and an ingredient (C): a catalyst.

Hereinafter, the optical adhesive having the above ingredients may be simply referred to as “the optical adhesive of the present disclosure” or simply as “the optical adhesive”. In addition, the ingredient (A) of a resin prepolymer having a straight side-chain may be simply referred to as “the ingredient (A) of the present disclosure” or simply as “ingredient (A)”. Similarly, the ingredient (B) of a crosslinking agent may be simply referred to as “the ingredient (B) of the present disclosure” or simply as “ingredient (B)”; and the ingredient (C) of a catalyst may be simply referred to as “the ingredient (C) of the present disclosure” or simply as “ingredient (C)”.

The optical adhesive of the present disclosure has a good creep resistance and a good stress absorption effect due to the specific structure of ingredient (A) and the suitable crosslinking degree-controlling property of ingredient (B). As a result, the optical adhesive of the disclosure is well-suited for use as an adhesive layer of a flexible panel or a flexible composite substrate.

### <Ingredient (A)>

The ingredient (A) of the present disclosure is a resin prepolymer having a straight side-chain. Ingredient (A) is obtained by reacting the following composition (ingredient (A)'s reactant composition): (a) 10-40 parts by weight of a soft monomer, which may be a soft acrylate monomer having a straight-chain or a mixture of a soft acrylate monomer having a straight-chain (a first soft monomer) and a soft monomer having a Tg≤0° C. (a second soft monomer); (b) 2-15 parts by weight of a hard monomer which may be an unsaturated ethylene double-bond monomer, or a mixture of an unsaturated ethylene double-bond monomer (a first hard monomer) and a hard acrylic monomer (a second hard monomer); (c) 1 part by weight of a hydroxyl-containing monomer; and (d) 0.001-0.03 parts by weight of a thermal initiator.

### [Soft Monomer]

In some embodiments, based on 1 part by weight of the (c) hydroxyl-containing monomer in the ingredient (A)'s reactant composition, an amount of the (a) soft monomer of the present disclosure may be 10-40 parts by weight, such as 10-30 parts by weight or 10-20 parts by weight.

In some embodiments, the (a) soft monomer used in the ingredient (A)'s reactant composition of the present disclosure may be a soft acrylate monomer having a straight-chain. The soft acrylate monomer may have a structure represented by Formula (I):

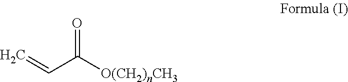

wherein n is an integer of 7 to 15, but not limited thereto.

In some embodiments, a specific example of the soft acrylate monomer having a straight-chain is not particularly limited and for example, may be selected from the group consisting of n-octyl (meth)acrylate, n-decyl (meth)acrylate, lauryl (meth)acrylate (LA), myristyl (meth)acrylate and palmityl (meth)acrylate.

To improve the creep resistance and stress absorption effect of the optical adhesive, the soft acrylate monomer having a straight-chain may be LA, and its structure is represented by Formula (I-1).

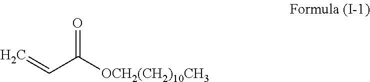

In some embodiments, the (a) soft monomer of the ingredient (A)'s reactant composition of the present disclosure may further optionally include, in addition to the soft acrylate monomer having a straight-chain (the first soft monomer), a soft monomer having a Tg≤0° C. (the second soft monomer). An amount of the second soft monomer may account for at most 60 wt %, based on the total weight of the (a) soft monomer (i.e., the sum of the weight of the first soft monomer and the second soft monomer). That is to say, an amount of the second soft monomer may be 0 wt %-60 wt % of the (a) soft monomer, such as 0 wt %-50 wt %, 0 wt %-45 wt %, 0 wt %-40 wt %, 0.1 wt %-60 wt %, 0.1 wt %-50 wt %, or 1 wt %-50 wt %.

In some embodiments, the soft monomer having a Tg≤0° C. specifically may be selected from the group consisting of butyl (meth)acrylate, sec-butyl (meth)acrylate, ethyl (meth)acrylate, 2-ethylhexyl (meth)acrylate (2-EHA), ethoxyethyl (meth)acrylate and isononyl (meth)acrylate.

To improve the creep resistance and stress absorption effect of the optical adhesive, the soft monomer with a Tg≤0° C. may be 2-EHA, and its structure is represented by Formula (II).

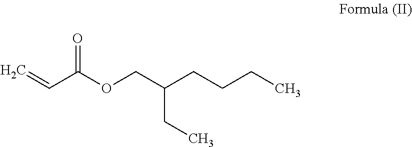

### [Hard Monomer]

In some embodiments, based on 1 part by weight of the (c) hydroxyl-containing monomer in the ingredient (A)'s reactant composition, an amount of the (b) hard monomer of the present disclosure may be 2-15 parts by weight, such as 2-13 parts by weight, 2-10 parts by weight, 3-13 parts by weight or 3-10 parts by weight.

In some embodiments, the (b) hard monomer used in the present disclosure may be a hard monomer having a Tg≥85° C., but not limited thereto.

In some embodiments, the (b) hard monomer of the ingredient (A)'s reactant composition of the present disclosure may be an unsaturated ethylene double-bond monomer.

In some embodiments, a specific example of the (b) hard monomer of the unsaturated ethylene double-bond monomer of the present disclosure is not particularly limited and for example, may be selected from the group consisting of acrylonitrile, acrylamide, acryloyl morpholine and N-vinyl-2-pyrrolidone (NVP).

To improve the creep resistance and stress absorption effect of the optical adhesive, the unsaturated ethylene double-bond monomer may be NVP, and its structure is represented by Formula (III).

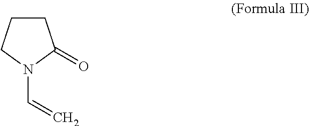

In some embodiments, the (b) hard monomer of the ingredient (A)'s reactant composition of the present disclosure may further optionally include, in addition to the unsaturated ethylene double-bond monomer (the first hard monomer), a hard acrylic monomer (the second hard monomer). In some embodiments, an amount of the hard acrylic monomer (the second hard monomer) may account for at most 40 wt %, based on the total weight of the (b) hard monomer (i.e., the sum of the weight of the first hard monomer and the second hard monomer), that is to say, an amount of the hard acrylic monomer (the second hard monomer) may be 0 wt %-40 wt % of the (b) hard monomer, such as 0 wt %-30 wt %, 0 wt %-25 wt %, 1 wt %-40 wt %, 1 wt %-35 wt % or 1 wt %-30 wt %.

In some embodiments, a specific example of the hard acrylic monomer (the second hard monomer) is not particularly limited and for example, may be selected from the group consisting of tert-butyl (meth)acrylate), butyl methacrylate, cyclohexyl (meth)acrylate, isobornyl (meth)acrylate (IBOA) and methyl (meth)acrylate.

To improve the creep resistance and stress absorption effect of the optical adhesive, the hard acrylic monomer (the second hard monomer) of the present disclosure may be IBOA, and its structure is represented by Formula (IV).

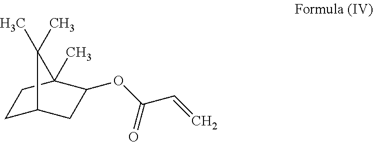

### [Hydroxyl (—OH)-Containing Monomer]

In some embodiments, the (c) hydroxyl-containing monomer of the ingredient (A)'s reactant composition of the present disclosure specifically may be selected from the group consisting of hydroxyethyl (meth)acrylate, hydroxypropyl (meth)acrylate, hydroxybutyl (meth)acrylate (4-HBA), hydroxypentyl (meth)acrylate and hydroxyhexyl (meth)acrylate.

To improve the creep resistance and stress absorption effect of the optical adhesive, the (c) hydroxyl-containing monomer may be 4-HBA, and its structure is represented by Formula (V).

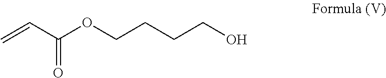

### [Thermal Initiator]

The content of the (d) thermal initiator used in the ingredient (A)'s reactant composition of the present disclosure is not particularly limited and may be adjusted as necessary depending on the type and amount of the selected monomers and the desired degree of polymerization. In some embodiments, based on 1 part by weight of the (c) hydroxyl-containing monomer in the ingredient (A)'s reactant composition of the present disclosure, an amount of the (d) thermal initiator may be 0.001-0.03 parts by weight.

In some embodiments, a specific example of the thermal initiator may be selected from the group consisting of azobisisobutyronitrile (AIBN), benzoyl peroxide, cumyl hydroperoxide, dicumyl peroxide, tert-butyl hydroperoxide, tert-butyl monoperoxymaleate, diacetyl peroxide and dilauroyl peroxide, but not limited thereto.

To improve the creep resistance and stress absorption effect of the optical adhesive, the thermal initiator may be AIBN and its structure is represented by Formula (VI).

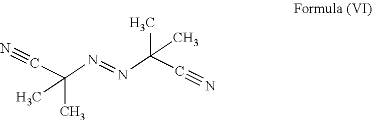

### <Ingredient (B)>

The ingredient (B) of the present disclosure is a crosslinking agent for controlling the crosslinking degree of the optical adhesive. Based on 100 parts by weight of the ingredient (A) of the present disclosure, an amount of the ingredient (B) may be 0.02-1 parts by weight.

The ingredient (B) of the present disclosure may be selected as necessary depending on the type and amount of other selected monomers and the desired degree of crosslinking.

In some embodiments, a specific example of the ingredient (B) of the present disclosure may be an organic peroxide or an isocyanate, but not limited thereto.

In some embodiments, the organic peroxide may be tetrahydrofuran peroxide, ethylene glycol dimethyl ether peroxide, benzoyl peroxide, methyl ethyl ketone peroxide, triacetone triperoxide, peroxyacetyl nitrate, diethylene oxide, peracetic acid, diethyl ether peroxide, cumene hydroperoxide and the like.

In some embodiments, the isocyanate may be a monoisocyanate, a polyisocyanate and the like, wherein the polyisocyanate may be as toluene diisocyanate (TDI), isophorone diisocyanate (IPDI), diphenylmethane diisocyanate (MDI), dicyclohexylmethane diisocyanate (H12MDI) and lysine diisocyanate (LDI).

In some embodiments, the ingredient (B) of the present disclosure may be commercially available, such as Desmodur® N3200 (a biuret type of hexamethylene diisocyanate) manufactured by Covestro.

### <Ingredient (C)>

The ingredient (C) of the present disclosure is a catalyst, and based on 100 parts by weight of the ingredient (A) of the present disclosure, an amount of the ingredient (C) may be 0.005-0.01 parts by weight.

In some embodiments, for environmental reasons, the ingredient (C) of the present disclosure may be an organometallic catalyst. Specifically, the ingredient (C) of the present disclosure may be a tin-free catalyst.

In some embodiments, the ingredient (C) of the present disclosure may be commercially available, such as Borchi® Kat 0243 (a metal carboxylate tin-free catalyst), Borchi® Kat 15 (a tin-free catalyst based on zinc neodecanoate), and the like manufactured by Borchers (Milliken).

### [Laminate for Flexible Panel]

Some embodiments of the present disclosure may further provide a laminate for a flexible panel, including an optical adhesive; and at least one substrate. The optical adhesive may be arranged on a surface of the substrate, and may further be sandwiched between two substrates to form a three-layer laminate structure.

In some embodiments, the substrate may be made of a material selected from the group consisting of polymethyl methacrylate (PMMA), polycarbonate (PC), polyethylene terephthalate (PET), polyvinyl chloride (PVC), thermoplastic polyurethane (TPU) elastomer, a styrene-acrylonitrile copolymer (AS) and polyimide (PI).

### Examples and Comparative Examples

The present disclosure will be described in more detail with reference to the following listed examples, but the present disclosure is not limited to these examples.

### Synthesis Examples 1 to 7 of Resin Prepolymer Having Straight Side-Chain

First, according to the contents of Table 1, 10% of monomer compositions and 25% of a solvent (ethyl acetate) were weighed and put into a 3-neck-flask equipped with a reflux condenser and dropping funnel, then the remaining 90% of the monomer compositions, azobisisobutyronitrile (as a thermal initiator) and the remaining 75% of the solvent (ethyl acetate) were mixed and dropwise added to the above flask over a feeding period of 8 hours. When the addition was complete, the mixture was heated to reflux (about 80° C.) and stirred at the rate of 200 rpm for reacting for 40 hours. Then the heating was stopped, and 2,6-dibutyl-p-cresol (as a terminator) was added to quench the reaction mixture. After cooling to room temperature, stirring was stopped, and the mixture was collected. Thereby obtaining the mixtures including resin prepolymers (1) to (7), respectively.

Herein, the soft acrylate monomer having a straight-chain (the first soft monomer) is LA; the soft monomer having a Tg≤0° C. (the second soft monomer) is 2-EHA; the unsaturated ethylene double-bond monomer (the first hard monomer) is NVP and the hard acrylic monomer (the second hard monomer) is IBOA; the hydroxyl (—OH)-containing monomer is 4-HBA; and the thermal initiator is AIBN.

TABLE 1

| | | Synthesis Example | | | | | | |
|---|---|---|---|---|---|---|---|---|
| | | 1 | 2 | 3 | 4 | 5 | 6 | 7 |
| Reaction materials | | Weight (g) | | | | | | |
| Soft acrylate | LA | 0 | 95.1 | 190.4 | 228.1 | 285.2 | 380.2 | 190.4 |
| monomer having | | | | | | | | |
| a straight- | | | | | | | | |
| chain (first | | | | | | | | |
| soft monomer) | | | | | | | | |
| Soft monomer | 2-EHA | 291.3 | 218.6 | 145.7 | 116.6 | 72.9 | 0 | 145.7 |
| having a Tg ≤ | | | | | | | | |
| 0° C. (second | | | | | | | | |
| soft monomer) | | | | | | | | |
| Unsaturated | NVP | 77.8 | 77.8 | 77.8 | 77.8 | 77.8 | 77.8 | 92.91 |
| ethylene double- | | | | | | | | |
| bond monomer | | | | | | | | |
| (first hard | | | | | | | | |
| monomer) | | | | | | | | |
| Hard acrylic | IBOA | 21.7 | 21.7 | 21.7 | 21.7 | 21.7 | 21.7 | 0 |
| monomer (second | | | | | | | | |
| hard monomer) | | | | | | | | |
| Hydroxyl- | 4-HBA | 22.3 | 22.3 | 22.3 | 22.3 | 22.3 | 22.3 | 22.3 |
| containing | | | | | | | | |
| monomer | | | | | | | | |
| Thermal initiator | AIBN | 0.105 | 0.105 | 0.105 | 0.105 | 0.105 | 0.105 | 0.105 |
| Solvent | EA | 964.3 | 964.3 | 964.3 | 964.3 | 964.3 | 964.3 | 964.3 |
| Terminator | BHT | 1.65 | 1.65 | 1.65 | 1.65 | 1.65 | 1.65 | 1.65 |

| | | | | | | | |
|---|---|---|---|---|---|---|---|
| Total (g) | 1379 | 1401 | 1424 | 1432 | 1446 | 1468 | 1468 |
| Solid content (%) | 30.08 | 31.19 | 32.28 | 32.68 | 33.31 | 34.31 | 31.95 |
| mixture including | (1) | (2) | (3) | (4) | (5) | (6) | (7) |
| resin prepolymer | | | | | | | |

### [Preparation of Optical Adhesive]

### Experimental Examples 1 to 6 and Comparative Examples 1 to 5

First, according to the contents of Tables 2-3, 300 g of the above mixture (includes about 90-100 g of solids) including resin prepolymers (1) to (7), 1.86 g of 1% catalyst (Borchi® Kat 0243) and various amounts of a crosslinking agent (Desmodur® N3200) were respectively weighed and put into a beaker and stirred uniformly, thereby obtaining optical adhesives (A) to (K) of Experimental Examples 1 to 6 and Comparative Examples 1 to 5.

The optical adhesives (A) to (K) were respectively coated onto release films H350A (manufactured by Nanya Plastics; model: NYN YA Release Film H350A) by a wet-coating process at a coating speed of 0.3-0.5 m/min, and the air duct was set at 65° C./80° C./90° C.-120° C. The coated films were then dried in an oven. After that, a second release film L150A (manufactured by Nanya Plastics; model: NYN YA Release Film L150A) was bonded to the opposite side of the surface of each optical adhesive. A three-layer structures of release film H350A-optical adhesive-release film L150A were obtained after winding and curing at 50° C. for 24 hours. Films (with a thickness of 100 μm) of optical adhesives (A) to (K) were obtained after the release films at both sides were removed. Various physical properties of the optical adhesives were measured according to the following methods and the results are collated in Tables 2-3.

### [Determination of Poisson's Ratio]

Poisson's ratio (Y) is respectively obtained by bonding the films made of the optical adhesives (A) to (K) to a substrate and tested using a universal tensile machine at room temperature, obtaining (E) the Young's modulus and (G) the shear modulus, and is calculated by the following equation according to the contents of “method of shear force test and calculation of Poisson's ratio” described in the reference” Application of the Finite Element Method in the Tensile-Shear Test of Adhesive Technology” (doi: 10.1016/S0143-7496 (01) 00012-4) authored by A. Öchsner et al.

$$γ = \frac{E}{2 G} - 1$$

### [Measurement of Relaxation Time (Creep Resistance)]

The films made of the optical adhesives (A) to (K) were bonded to a substrate and tested using a tensile machine at room temperature, stretched to 50% strain, held for 15 minutes, and then released. The recovery time required for the adhesive films after relaxation was measured and defined as “relaxation time” in the unit of “seconds”.

### [Peel Adhesion Test]

One sides of the films (thickness of 100 μm) made of the optical adhesives (A) to (K) were bonded to a support material of 1.0 mm thick and the other sides were bonded to transparent PI films (manufactured by Microcosm Technology Co., LTD.; model: MCF025) to obtain samples with a width of 24±0.5 mm. The transparent PI films were stretched and peeled at a constant rate of 300 mm/min using parameters that stimulated the ASTM D3330 arrangement, thereby measuring the peel adhesion of the optical adhesives (A) to (K).

### [Test of Thermal Warpage Deformation Quantity at High Temperature and High Humidity]

As described above, after preparing the three-layer structures of release film H350A-optical adhesives (A) to (K)-release film L150A, the release films L150A were removed and transparent PI films were bonded to the exposed optical adhesive surfaces, then the release film H350A were removed and polymethyl methacrylate (PMMA) support materials were bonded to the then exposed optical adhesive surfaces to obtain laminated samples with a length of 76.4 mm. The laminated samples were then placed on metal substrates, and were subjected to a high-temperature and high-humidity environment at 85° C./85% for 4 hours, the deformation quantities of the laminated bodies were measured and the results were defined as “thermal warpage deformation quantity at high temperature and high humidity” of the optical adhesives (A) to (K).

TABLE 2

| | Experimental Example | | | | | |
|---|---|---|---|---|---|---|
| | Exam- | Exam- | Exam- | Exam- | Exam- | Exam- |
| | ple 1 | ple 2 | ple 3 | ple 4 | ple 5 | ple 6 |
| mixture | (3) | (3) | (4) | (5) | (6) | (7) |
| including | | | | | | |
| resin | | | | | | |
| prepolymer | | | | | | |
| Percentage of | 17.0 | 17.0 | 16.7 | 16.2 | 15.5 | 20.6 |
| NVP | | | | | | |
| accounting for | | | | | | |
| the total | | | | | | |
| weight (wt. %) | | | | | | |
| Percentage of | 4.7 | 4.7 | 4.7 | 4.5 | 4.3 | 0 |
| IBOA | | | | | | |
| accounting for | | | | | | |
| the total | | | | | | |
| weight (wt. %) | | | | | | |
| Percentage of | 4.9 | 4.9 | 4.8 | 4.6 | 4.4 | 4.9 |
| 4-HBA | | | | | | |
| accounting for | | | | | | |
| the total | | | | | | |
| weight (wt. %) | | | | | | |
| Percentage of | 31.8 | 31.8 | 25.0 | 15.2 | 0.0 | 32.3 |
| 2-EHA | | | | | | |
| accounting for | | | | | | |
| the total | | | | | | |
| weight (wt. %) | | | | | | |
| Percentage of | 41.6 | 41.6 | 48.9 | 59.4 | 75.7 | 42.2 |
| LA | | | | | | |
| accounting for | | | | | | |
| the total | | | | | | |
| weight (wt. %) | | | | | | |
| Weight of | 1.86 | 1.86 | 1.86 | 1.86 | 1.86 | 1.86 |
| catalyst | | | | | | |
| (1%) (g) | | | | | | |
| Crosslinking | 0.15 | 0.23 | 0.23 | 0.23 | 0.23 | 0.23 |
| agent (g) | | | | | | |
| Optical | (A) | (B) | (C) | (D) | (E) | (F) |
| adhesive | | | | | | |
| Poisson's | 0.43 | 0.43 | 0.47 | 0.48 | 0.49 | 0.42 |
| ratio | | | | | | |
| Relaxation | 32 | 40 | 38 | 30 | 25 | 59 |
| time (s) | | | | | | |
| 180° peel | 11.3 | 15.5 | 15.0 | 14.3 | 12.8 | 10.5 |
| adhesion | | | | | | |
| (>10 N/in) | | | | | | |
| Peel test | OCA-PI | OCA-PI | OCA-PI | OCA-PI | OCA-PI | OCA-PI |
| (Failure | | | | | | |
| interface) | | | | | | |
| High- | 0 | 0 | 0 | 0 | 0 | 0 |
| temperature | | | | | | |
| and high- | | | | | | |
| humidity | | | | | | |
| thermal | | | | | | |
| warpage | | | | | | |
| deformation | | | | | | |
| quantity | | | | | | |
| (<0.1 mm) | | | | | | |

TABLE 3

| | Comparative | Comparative | Comparative | Comparative | Comparative |
|---|---|---|---|---|---|
| Comparative Example | Example 1 | Example 2 | Example 3 | Example 4 | Example 5 |
| mixture including | (1) | (2) | (3) | (3) | (3) |
| resin prepolymer | | | | | |
| Percentage of NVP | 18.8 | 17.9 | 17.0 | 17.0 | 17.0 |
| accounting for the total | | | | | |
| weight (wt. %) | | | | | |
| Percentage of IBOA | 5.3 | 5.0 | 4.7 | 4.7 | 4.7 |
| accounting for the total | | | | | |
| weight (wt. %) | | | | | |
| Percentage of 4-HBA | 5.4 | 5.1 | 4.9 | 4.9 | 4.9 |
| accounting for the total | | | | | |
| weight (wt. %) | | | | | |
| Percentage of 2-EHA | 70.5 | 50.2 | 31.8 | 31 | 31.8 |
| accounting for the total | | | | | |
| weight (wt. %) | | | | | |
| Percentage of LA | 0.0 | 21.8 | 41.6 | 41.6 | 41.6 |
| accounting for the total | | | | | |
| weight (wt. %) | | | | | |
| Weight of catalyst | 1.86 | 1.86 | 1.86 | 1.86 | 1.86 |
| (1%) (g) | | | | | |
| Crosslinking agent (g) | 0.23 | 0.23 | 0.37 | 0.07 | 0.5 |
| Optical adhesive | (G) | (H) | (I) | (J) | (K) |
| Poisson's ratio | 0.43 | 0.41 | 0.41 | 0.46 | 0.38 |
| Relaxation time (s) | 420 | 73 | 51 | 20 | 68 |
| 180° peel adhesion | 17.4 | 17.0 | 13.5 | 8.3 | 9.7 |
| (>10 N/in) | | | | | |
| Peel test (Failure | OCA-PI | OCA-PI | OCA-PI | OCA | OCA-PI |
| interface) | | | | | |
| High-temperature and | 2.3 | 0.4 | 0.2 | 0 | 0.3 |
| high-humidity thermal | | | | | |
| warpage deformation | | | | | |
| quantity (<0.1 mm) | | | | | |

According to the results of Tables 2-3, compared with the optical adhesives (A) to (F) of the present disclosure, the optical adhesives (G) to (H) use less amount of soft acrylate monomers having a straight-chain. The optical adhesives (G) to (H) have longer relaxation times and have greater thermal warpage deformation quantities at high temperature and high humidity. The optical adhesive (I) includes a higher amount of crosslinking agents, and has greater thermal warpage deformation quantity at high temperature and high humidity than that of the optical adhesives (A) to (F) of the present disclosure, optical adhesive (I) also has a longer relaxation time. In addition, the optical adhesives (J) to (K) include fewer crosslinking agents, and have poorer peel test results than that of the optical adhesives (A) to (F) of the present disclosure. The optical adhesive (K) has a longer relaxation time.

In addition, after the optical adhesives (A) to (K) are bonded to PMMA support materials and PI films, peel tests are performed and the results of the failure interface are shown in Tables 2 and 3. The optical adhesive (J) shows adhesive residual on both sides of the PI and PMMA (the degree of crosslinking of the optical adhesive (J) is too small; cohesion failure occurs at the optical adhesive layer), and the rest of the optical adhesives show no residual on the PI side (failure interface is at OCA (optical clear adhesive)-PI interface).

As shown in the above results, the optical adhesive of some embodiments of the present disclosure has good creep resistance (low “relaxation time”) and stress absorption effect (low “high-temperature and high-humidity thermal warpage deformation quantity”), making it suitable for application as flexible panels and the like.

Although the technical contents of the present disclosure have been disclosed in preferred embodiments, rather than used to limit the present disclosure, some changes and modifications made by those skilled in the art without departing from the spirit of the present disclosure shall be covered in the scope of the present disclosure. Therefore, the protection scope of the present disclosure should be determined by the appended claims.

What is claimed is:

1. An optical adhesive, comprising:
100 parts by weight of an ingredient (A), wherein the ingredient (A) is a resin prepolymer having a straight side-chain;
0.02 to 1 part by weight of an ingredient (B), wherein the ingredient (B) is a crosslinking agent; and
0.005 to 0.01 parts by weight of an ingredient (C), wherein the ingredient (C) is a catalyst;
wherein the ingredient (A) is obtained by reacting a composition of:
(a) 10 to 40 parts by weight of a soft monomer, wherein the soft monomer comprising a soft acrylate monomer having a straight-chain, the soft acrylate monomer has a structure represented by Formula (I); 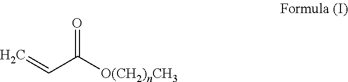
wherein n is an integer of 7 to 15;
(b) 2 to 15 parts by weight of a hard monomer, wherein the hard monomer comprising an unsaturated ethylene double-bond monomer;
(c) 1 part by weight of a hydroxyl-containing monomer; and
(d) 0.001 to 0.03 parts by weight of a thermal initiator.

2. The optical adhesive according to claim 1, wherein based on 1 part by weight of the hydroxyl-containing monomer, an amount of the soft monomer (a) of the composition is 10 to 20 parts by weight.

3. The optical adhesive according to claim 1, wherein based on 1 part by weight of the hydroxyl-containing monomer, an amount of the hard monomer (b) of the composition is 2 to 10 parts by weight.

4. The optical adhesive according to claim 1, wherein the soft monomer (a) further comprises a soft monomer having a Tg≤0° C. and an amount of the soft monomer having a Tg≤0° C. is at most 60 wt %, based on a total weight of the soft monomer (a).

5. The optical adhesive according to claim 4, wherein an amount of the soft monomer having a Tg≤0° C. is 0.1 wt % to 50 wt %, based on the total weight of the soft monomer.

6. The optical adhesive according to claim 1, wherein the hard monomer (b) further comprises a hard acrylic monomer and an amount of the hard acrylic monomer is at most 40 wt %, based on a total weight of the hard monomer (b).

7. The optical adhesive according to claim 6, wherein an amount of the hard acrylic monomer is 1 wt %-40 wt %, based on the total weight of the hard monomer (b).

8. The optical adhesive according to claim 1, wherein the unsaturated ethylene double-bond monomer is selected from the group consisting of acrylonitrile, acrylamide, acryloyl morpholine, and N-vinyl-2-pyrrolidone.

9. The optical adhesive according to claim 6, wherein the hard acrylic monomer is selected from the group consisting of tert-butyl (meth)acrylate, butyl methacrylate, cyclohexyl (meth)acrylate, isobornyl (meth)acrylate and methyl (meth)acrylate.

10. The optical adhesive according to claim 1, wherein the soft acrylate monomer having a straight-chain represented by Formula (I) is selected from the group consisting of n-octyl (meth)acrylate, n-decyl (meth)acrylate, lauryl (meth)acrylate, myristyl (meth)acrylate, and palmityl (meth)acrylate.

11. The optical adhesive according to claim 1, wherein the hydroxyl-containing monomer is selected from the group consisting of hydroxyethyl (meth)acrylate, hydroxypropyl (meth)acrylate, hydroxybutyl (meth)acrylate, hydroxypentyl (meth)acrylate and hydroxyhexyl (meth)acrylate.

12. The optical adhesive according to claim 4, wherein the soft monomer having a Tg≤0° C. is selected from the group consisting of butyl (meth)acrylate, sec-butyl (meth)acrylate, ethyl (meth)acrylate, 2-ethylhexyl (meth)acrylate, ethoxyethyl (meth)acrylate, and isononyl (meth)acrylate.

13. A laminate for a flexible panel, comprising:
the optical adhesive according to claim 1; and
a substrate;
wherein the optical adhesive is arranged on a surface of the substrate; and
the substrate is made of a material selected from the group consisting of polymethyl methacrylate (PMMA), polycarbonate (PC), polyethylene terephthalate (PET), polyvinyl chloride (PVC), thermoplastic polyurethane (TPU) elastomer, a styrene-acrylonitrile copolymer (AS), and polyimide (PI).
